(19) United States
(12) Patent Application Publication
(10) Pub. No.: US 2023/0147273 A1
(43) Pub. Date: May 11, 2023

(54) Warpage Compensation for BGA Package

(71) Applicant: Apple Inc., Cupertino, CA (US)

(72) Inventors: Brett W. Degner, Menlo Park, CA (US); Jie-Hua Zhao, Cupertino, CA (US); Kristopher P. Laurent, Portola Valley, CA (US); Michael E. Leclerc, Mountain View, CA (US); Rangaraj Dhanasekaran, San Jose, CA (US); Simon J. Trivett, Waterloo (CA)

(21) Appl. No.: 17/821,920

(22) Filed: Aug. 24, 2022

Related U.S. Application Data
(60) Provisional application No. 63/276,449, filed on Nov. 5, 2021.

(51) Int. Cl. H01L 23/00; H01L 25/16; H01L 25/065; H01L 23/498; H01L 21/48

(52) U.S. Cl. CPC H01L 23/562; H01L 25/16; H01L 25/0655; H01L 24/16; H01L 24/32; H01L 24/73; H01L 23/49816; H01L 21/4817; H01L 21/4853; H01L 24/81; H01L 2924/3025; H01L 2924/3511; H01L 2924/1431; H01L 2924/1432; H01L 2924/1436; H01L 2224/73253; H01L 2224/32245; H01L 2224/16225; H01L 2224/81097; H01L 2924/1616; H01L 2924/16235; H01L 2924/16251; H01L 2924/1632; H01L 2924/1659

(57) ABSTRACT

Electronic assemblies and methods of assembly are described. In an embodiment, an electronic assembly includes a stiffener structure shear bonded to an opposite side of a module substrate from a ball grid array (BGA) package. The stiffener structure may be shear bonded at elevated temperature after bonding of the BGA package to lock in a flat or near-flat surface contour of the module substrate.

### RELATED APPLICATIONS

This application claims the benefit of priority of U.S. Provisional Application No. 63/276,449 filed Nov. 5, 2021 which is herein incorporated by reference.

### FIELD

Embodiments described herein relate to electronic packaging, and in particular to stiffener structures.

### BACKGROUND INFORMATION

As microelectronic packages become thinner and larger in size, structures are also being implemented within the microelectronic packages to control warpage at room and high temperatures. For example, stiffener structures are widely used in multiple chip modules (MCMs) for warpage, reliability and thermal performance. In an exemplary implementation one or more devices are surface mounted onto a module substrate, and then optionally underfilled. A stiffener structure is then secured onto the module substrate and surrounding the device(s). Stiffener structures are commonly bonded to the package module with adhesive tapes such as urethane, polyurethane, silicone elastomers, etc.

### SUMMARY

In an embodiment, an electronic assembly includes a module substrate with a first side and a second side opposite the first side, a ball grid array (BGA) package bonded to the first side of the module substrate, and a stiffener structure bonded to the second side of the module substrate. The stiffener structure may span an area directly opposite the module substrate of the BGA package, and be shear bonded to the second side of the module substrate. In accordance with embodiments, shear bonding may be performed at elevated temperature where the BGA package is intrinsically flatter, and with a suitable material such as solder material or thermoset material to accomplish shear bonding and provide rigidity and modulus to lock in a flat or near-flat surface contour.

### BRIEF DESCRIPTION OF THE DRAWINGS

FIGS. 1A-1E are schematic cross-sectional side view illustrations of a method of forming an electronic assembly with a stiffener structure and BGA package bonded to opposite sides of a module substrate in accordance with an embodiment.

FIG. 2 is a flow diagram for a method of forming an electronic assembly with stiffener structure and BGA package bonded to opposite sides of a module substrate in accordance with an embodiment.

FIG. 3 is a schematic bottom view illustration of a stiffener structure bonded to a module substrate in accordance with an embodiment.

FIG. 4 is a schematic cross-sectional side view illustration of an electronic assembly with separate lid bonded to a stiffener structure in accordance with an embodiment.

FIG. 5 is a schematic cross-sectional side view illustration of an electronic assembly and stiffener structure with integrated lid in accordance with an embodiment.

### DETAILED DESCRIPTION

Embodiments describe electronic assemblies and methods of assembly including bonding of a stiffener structure at elevated temperature on the opposite side of a module substrate from a mounted ball grid array (BGA) package to control warpage.

In one aspect, it has been observed that ball grid array (BGA) packages can create local and global warpage on module substrates (e.g. printed circuit boards) due to stiffness and coefficient of thermal expansion (CTE) differences, resulting in un-flat module assemblies that can change over storage and operating temperature ranges. Moreover, such un-flat module assemblies can add to critical thickness of the electronic assembly, be problematic form mating assemblies such as thermal solutions (e.g. stiffener structures, lids), and shape changes across a temperature range can contributed to cyclic stress failures in the module substrate layers or solder joints, such as BGAs.

In accordance with embodiments, compensation designs and processes are described for controlling warpage of a module substrate with BGA component(s) across a range of temperatures. In various aspects, stiffener structures can be bonded to an opposite side of a module substrate from a BGA package and also be bonded at elevated temperatures locking in a near-flat surface contour of the module substrate that is fundamental for BGA design. As a result, overall electronic system design for housing the electronic assembly can be with a reduced z-height, and overall thinner product.

In one aspect, it has been observed that intrinsically stressed BGA packages are designed to flatten at their reflow temperatures to ensure uniform joint formation. In accordance with embodiments, the stiffener structures can also be bonded at elevated temperatures, which are below the BGA package reflow temperatures yet sufficiently high to return the BGA packages to flat or near flat shapes. The bonding materials for the stiffener structures can be selected to provide sufficient Young's Modulus (also generally referred to as modulus), stiffness and adhesion strength to provide shear bonding with the module substrate and transfer the mechanical properties of the stiffener structure to the module substrate. As a result, warpage may be controlled across a range of operating temperatures for the electronic assembly.

In an embodiment, an electronic assembly includes a module substrate including a first side and a second side opposite the first side, a BGA package bonded to the first side of the module substrate (for example, with a high temperature solder), and a stiffener structure bonded to the second side of the module substrate (for example, with a low-medium temperature solder) to achieve shear bonding. The stiffener structure may span an area directly opposite the module substrate of the BGA package to match the BGA package with modulus, geometry, coefficient of thermal expansion, flatness, etc.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “over”, “to”, “between”, “spanning” and “on” as used herein may refer to a relative position of one layer with respect to other layers. One layer “over”, “spanning” or “on” another layer or bonded “to” or in “contact” with another layer may be directly in contact with the other layer or may have one or more intervening layers. One layer “between” layers may be directly in contact with the layers or may have one or more intervening layers.

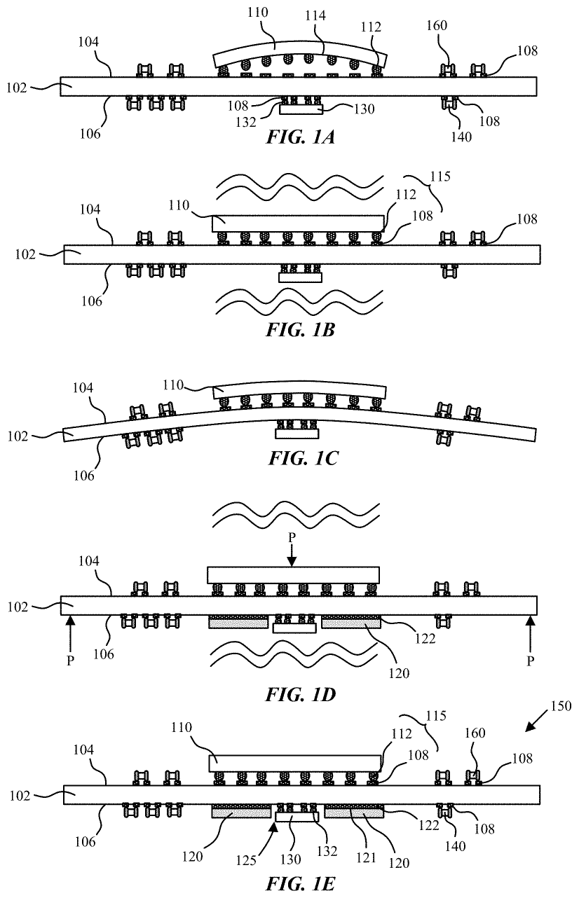

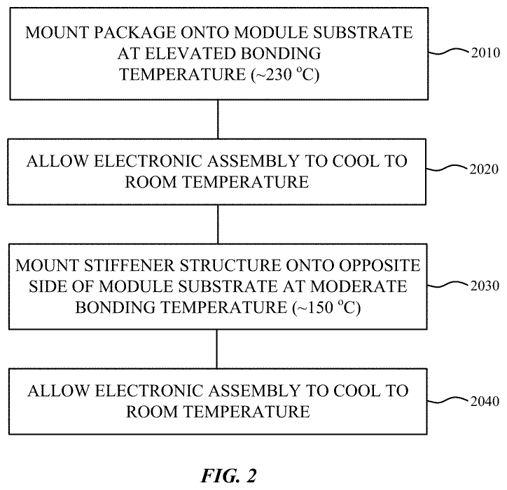

Referring now to FIGS. 1A-1E and FIG. 2, FIGS. 1A-1E are schematic cross-sectional side view illustrations of a method of forming an electronic assembly with a stiffener structure and BGA package bonded to opposite sides of a module substrate in accordance with an embodiment; FIG. 2 is a flow diagram for a method of forming an electronic assembly with stiffener structure and BGA package bonded to opposite sides of a module substrate in accordance with an embodiment. In interest of clarity and conciseness the sequence of schematic cross-sectional side view illustrations of FIGS. 1A-1E are discussed concurrently with the flow diagram of FIG. 2.

In the exemplary embodiment, the electronic assembly includes a module substrate 102 including a first side 104 and second side 106. For example, module substrate 102 may be a printed circuit board (PCB), which may a rigid board and be cored or coreless. A plurality of first components 160 can be mounted on the first side 104 of the module substrate 102. A plurality of second components 140 can be mounted on the second side 106 of the module substrate 102. In accordance with embodiments, both the first components 160 and second components 140 can be mounted onto the module substrate 102 prior to mounting a BGA package 110 onto the first side 104 of the module substrate 102. Furthermore, one or more second packages 130 can be mounted onto the second side 106 of the module substrate 102 prior to mounting BGA package 110. In accordance with embodiments, the BGA package 110 may be a comparatively large package that occupies a larger area of the module substrate than the individual first and second components 160, 140 and second package(s) 130. Furthermore, the BGA package 110 may include an intrinsic stress, which is illustrated by the crowning shape in FIG. 1A. The BGA package 110 in accordance with embodiments may perform high density logic, and may for example include central processing unit (CPU) die, graphics processing unit (GPU) die, system on chip (SoC) die, various engines, etc. that includes a high performance logic area that may include a high density of devices that tend to run hot, and transfer BGA package 110 stress to the module substrate 102. First components 160 and second components 140 may be passive devices (e.g. resistor, inductor, capacitor, etc.) or active devices, and may be chips or packages. For example, first and second components 160, 140 may be memory packages, such as dynamic random-access memory (DRAM) including one or more dies, which can be stacked dies, or side-by-side. First and second components 160, 140 can additionally be different types of components, and need not be identical. One or more second packages 130 can also be mounted on the second side 106 of the module substrate 102. In an embodiment, a second package 130 is a package that includes a single die or a plurality (e.g. two or more) of side-by-side dies. For example, second package 130 may include a plurality of side-by-side logic, or system on chip dies. In an embodiment, second package(s) 130 are chip scale packages providing different circuit functionality (logic, power management, integrated voltage regulator, etc.).

Referring now to FIG. 1B, at operation 2010 the BGA package 110 is mounted onto the first side 104 of the module substrate 102 at elevated temperature. As illustrated by the wavy lines, heat is applied globally to reflow solder bumps 112 applied to the bottom side 114 of the BGA package 110. For example, the solder bumps 112 may mate with corresponding solder pads 108 on the module substrate 102 to form joints. In an embodiment, the BGA package 110 is bonded to the first side 104 of the module substrate 102 with a plurality of solder joints 115 characterized by a melting temperature greater than 200° C. For example, the elevated temperature, or reflow temperature, for bonding may be approximately 230° C. Specifically, the BGA package 110 may have been designed to a have a flat or near-flat shape at the elevated bonding temperature in order to achieve uniform joint formation.

In accordance with embodiments, the first and second components 160, 140 and second package(s) 130 can have also been bonded to the module substrate 102 with one or more bonding materials 132 and solder pads 108 characterized by melting temperatures greater than 200° C. in order to withstand bonding of the BGA package 110.

The partially assembled electronic assembly can then be allowed to cool to room temperature at operation 2020. For example, this operation may be performed as general storage or transfer during assembly. Referring now to FIG. 1C, it has been observed that the BGA package 110 can create local and global warpage on the module substrate 102 due to stiffness and CTE differences, resulting an un-flat module substrate 102 and overall electronic assembly that can change over storage and operating temperatures. For example, the intrinsic BGA package 110 crowning illustrated in FIG. 1A can be transferred to the module substrate 102 as shown in FIG. 1C.

Still referring to FIG. 1C, it can be seen why the plurality of first and second components 160, 140 and second package 130 have been pre-assembled onto the module substrate prior to bonding the BGA package 110. As shown, the uneven surface profile caused by the BGA package 110 could result from difficulty in placement of solder pads 108 onto the module substrate, or even mounting of the additional components or second package 110, which could result in broken or incomplete joint formation.

Referring now to FIG. 1D, at operation 2030 a stiffener structure 120 is then mounted onto an opposite side (e.g. second side 106) of the module substrate 102 from the BGA package 110. In this case, bonding may be performed at a moderate bonding temperature of less than 200° C. to create a shear bonded interface with the second side of the module substrate. For example, the stiffener structure 120 can be bonded to the second side 106 of the module substrate 102 with a solder material characterized by a melting temperature between 150° C.-190° C., which can be below the reflow temperature of the BGA package 110 as well as first and second components 160, 140 yet above the operating temperature of the BGA package 110. More specifically, bonding or reflow temperature may be selected where the BGA package 110 intrinsically flattens. In a particular embodiment, the intrinsic BGA package 110 flattening and bonding or reflow temperature is between 150° C.-165° C. Alternatively, with the same bonding temperatures, the stiffener structure 120 can be bonded to the second side 106 of the module substrate 102 with a one or two part adhesive, for example, such as a glass paste or cured polymer (e.g. thermoset) such as polyimide, silicone epoxy, etc. to create a shear bonded interface with the second side of the module substrate.

In accordance with embodiments, the bonding material 122 is selected to achieve necessary stiffness, modulus (Young's Modulus) and adhesion strength with the module substrate to provide shear-coupling. This may be achieved by selection of suitable materials such as solder, glass paste, or cured polymers (e.g. thermoset materials) that can provide stiffness and adhesion strength that is greater than traditional adhesive tapes such as urethane, polyurethane, silicone elastomers, etc. For example, solder materials may have a modulus of greater than 20 GPa, such as 30-50 GPa, and a thermoset material such as epoxy or acrylonitrile butadiene styrene (ABS) may have a modulus of approximately 1-4 GPa, whereas a traditional pressure sensitive tape may have a modulus of less than 0.5 GPa. In accordance with embodiments, the bonding material 122 may have a Young's Modulus of greater than 1 GPa, or even greater than 20 GPa.

In accordance with embodiments, the moderate bonding temperature and optional pressure (P) applied to the module substrate 102 and/or BGA package 110 can return the assembly, including the BGA package 110 and module substrate 102, to a flat or near-flat state from when the BGA package was bonded. The stiffener structure 120 additionally is designed with specific materials, geometry, CTE, flatness, etc. and bonding material 122 is selected to achieve a specific modulus, stiffness, and adhesion strength with the module substrate 102 to provide shear-coupling and lock in a flat and stable electronic assembly across the operating temperature range of the electronic assembly. In an embodiment, the stiffener structure 120 can be formed of a high modulus, low CTE material to reduce stress and warpage of the module substrate 102. In an exemplary implementation a low CTE stiffener material can be a nickel-iron alloy (FeNi36), iron-nickel-cobalt alloy (sold under the trademark KOVAR, trademark of CRS Holdings, Inc., Delaware), iron-nickel alloy (Alloy42), stainless steels (SUS410, SUS430), etc. In an embodiment, the stiffener structure 120 is formed of a low CTE 400 series stainless steel, with a CTE around 11 ppm/° C. Other notable low CTE, high modulus materials include molybdenum and molybdenum-copper alloys, both having higher thermal conductivities that traditional high modulus, low CTE materials, which can be a thermal benefit to the BGA package as well as the components within the stiffener footprint. In accordance with embodiments, the modulus, thickness, geometry, CTE, bonding temperature and bonding material all work in concert to compensate the BGA package induced warpage.

The electronic assembly 150 may then be allowed to cool to room temperature at operation 2040, with module substrate 102 being flat or substantially flat as shown in FIG. 1E across the operating temperature range of the BGA package 110. In an embodiment, the module substrate 102 is characterized by a maximum curvature across an area of the BGA package 110 covering the first side of the module substrate of less than 100 μm. For example, this may represent a significant reduction in warpage, or crowning, for a similar module substrate 102 without such a stiffener structure, in which a total module height of 1.5 mm includes 200-300 μm of warpage, or crowning. Accordingly, embodiments may facilitate the assembly of an electronic assembly with reduced total z-height.

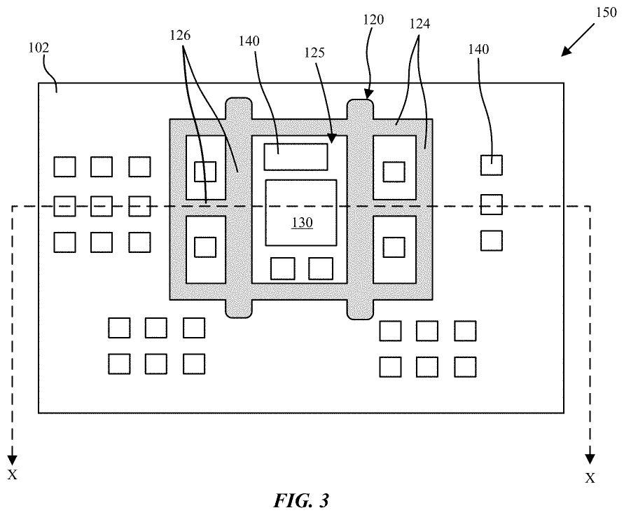

FIG. 3 is a schematic bottom view illustration of a stiffener structure 120 bonded to a module substrate 102 in accordance with an embodiment. Specifically, the electronic assembly 150 of FIG. 1E may correspond to a cross-section taken along section X-X of FIG. 3. As previously described, the second side of the module substrate 102 can be populated with a plurality of second components 140, which can be a variety of different active and passive components. Furthermore, the stiffener structure 120 can be frame-shaped including outer walls 124 (e.g. along a perimeter) and optional inner (interior) walls 126. The outer walls 124 and optional inner walls 126 can form one or more openings 125, which may optionally be fully enclosed. Such enclosure may optionally provide additional function of electromagnetic interference (EMI) shielding for one or more second components 140 or second packages 130 mounted to the second side of the module substrate 102. Use of an electrically conductive bonding material 122, such as solder material, can additionally facilitate EMI shielding. In accordance with embodiments, the bonding material 122 can be continuously or near continuously applied along the bottom surface 121 (see FIG. 1E) of the frame-shaped stiffener structure 120 rather than at separate and discrete locations. More specifically, the bonding material 122 can near continuously span along the bottom surface 121 for the lengths of one or more outer walls 124 and inner walls 126, though can be broken up to separate areas to better control distribution and uniformity of the bonding material. The more uniform and continuous the bonding, the greater and more consistent the shear coupling effect may be and the more effective the stiffener structure compensation. In an embodiment, a bond line covers approximately 90% of the stiffener structure footprint (e.g. bottom surface 121).

Referring to both FIG. 3 and FIGS. 1D-1E, in accordance with embodiments, the stiffener structure 120 may include an opening 125, and a second package 130 is mounted onto the second side 106 of the module substrate 102 within the opening 125. For example, the BGA package 110 can cover a larger area of the module substrate 102 than the opening 125 in the stiffener structure and the second package 130. Additionally components or packages can also be mounted within the opening(2) 125.

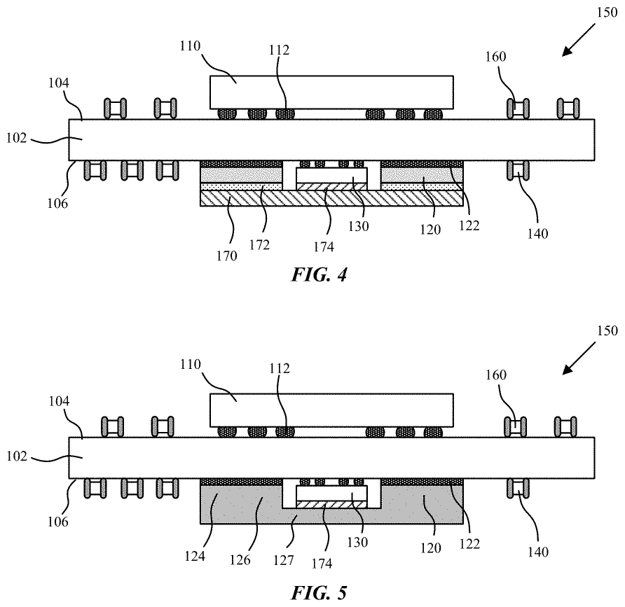

In some embodiments, the electronic assembly can include additional structures for EMI shielding and/or thermal function. For example, a lid can complete EMI shielding for components within the stiffener structure footprint. FIG. 4 is a schematic cross-sectional side view illustration of an electronic assembly 150 with separate lid 170 bonded to a stiffener structure 120 in accordance with an embodiment. The lid 170 may be bonded to the stiffener structure 120 with an electrically conductive adhesive or gasketing for example. In an embodiment, lid 170 is bonded to the stiffener structure 120 with an electrically conductive pressure sensitive adhesive 172 such as an adhesive tape formed of urethane, polyurethane, silicone elastomers, etc. and filled with conductive fillers, which may have a lower stiffness, modulus and adhesion strength to the stiffener structure 120 and the stiffener structure than does the bonding material 122 with the module substrate 102 and the stiffener structure 120. The lid 170 may be formed of the same or different material than the stiffener structure 120. For example, the lid 170 can optionally be formed of a more thermally conductive material such as copper, while still controlling warpage. Furthermore, a thermal interface material (TIM) 174 can be applied between the second package 130 and the lid 170. TIM 174 may be applied using any suitable technique such as dispensing or tape. Exemplary TIMs 174 include, but are not limited to, thermal grease, solder, metal filled polymer matrix, etc. In an embodiment, the lid 170 spans over the outer walls 124 and the inner walls 126 of the stiffener structure.

FIG. 5 is a schematic cross-sectional side view illustration of an electronic assembly 150 and stiffener structure 120 with integrated lid in accordance with an embodiment. In this manner, a roof 127 can ben integrally formed with the outer walls 124 and/or inner walls 126 as a single piece. A TIM 174 may still be applied between the second package 130 and roof 127 to facilitate heat transfer.

In utilizing the various aspects of the embodiments, it would become apparent to one skilled in the art that combinations or variations of the above embodiments are possible for forming an electronic assembly with stiffener structure to compensate for BGA package warpage. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. An electronic assembly comprising:
a module substrate including a first side and a second side opposite the first side;
a ball grid array (BGA) package bonded to the first side of the module substrate; and
a stiffener structure bonded to the second side of the module substrate, the stiffener structure spanning an area directly opposite the module substrate of the BGA package;
wherein the stiffener structure is shear bonded to the second side of the module substrate.

2. The electronic assembly of claim 1, wherein the BGA package is bonded to the first side of the module substrate with a plurality of solder joints characterized by a melting temperature greater than 200° C.

3. The electronic assembly of claim 2, wherein the stiffener structure is bonded to the second side of the module substrate with a solder material characterized by a melting temperature between 150° C.-190° C.

4. The electronic assembly of claim 2, wherein the stiffener structure is bonded to the second side of the module substrate with thermoset material.

5. The electronic assembly of claim 2, wherein the module substrate is characterized by a maximum curvature across an area of the BGA package covering the first side of the module substrate of less than 100 μm.

6. The electronic assembly of claim 2, wherein the stiffener structure includes an opening, and a second package is mounted onto the second side of the module substrate within the opening.

7. The electronic assembly of claim 6, wherein the BGA package covers a larger area of the module substrate than the opening in the stiffener structure.

8. The electronic assembly of claim 7, wherein the stiffener structure is frame shaped including a perimeter of outer walls, and inner walls.

9. The electronic assembly of claim 8, further comprising a lid bonded to the stiffener structure, and spanning over the outer walls and the inner walls.

10. The electronic assembly of claim 9, wherein the lid is bonded to the stiffener structure with a pressure sensitive adhesive.

11. The electronic assembly of claim 9, wherein the stiffener structure further comprises a roof integrally formed with the outer walls and the inner walls, and spanning over the outer walls and the inner walls.

12. The electronic assembly of claim 7, wherein the second package is mounted onto the second side of the module substrate is a bonding material characterized by a melting temperature greater than 200° C., and the stiffener structure is bonded to the second side of the module substrate with a solder material characterized by a melting temperature between 150° C.-190° C.

13. The electronic assembly of claim 2, wherein the stiffener structure is bonded to the second side of the module substrate with a bonding material characterized by a Young's Modulus of greater than 1 GPa.

14. The electronic assembly of claim 2, wherein the stiffener structure is bonded to the second side of the module substrate with a bonding material characterized by a Young's Modulus of greater than 20 GPa.

15. The electronic assembly of claim 14, wherein the bonding material is a solder material characterized by a melting temperature between 150° C.-190° C.

16. The electronic assembly of claim 15, wherein the solder material is near continuous along a bottom surface of one or more outer walls of the stiffener structure.

17. A method of assembling an electronic assembly comprising:
mounting a first plurality of first components onto a first side of a module substrate and a second plurality of second components onto a second side of a module substrate;
mounting a ball grid array (BGA) package onto the first side of the module substrate with a plurality of solder bumps characterized by a melting temperature greater than 200° C.; and
after mounting the BGA package, mounting a stiffener structure onto second side of the module substrate with at a moderate bonding temperature of less than 200° C. to create a shear bonded interface with the second side of the module substrate.

18. The method of claim 17, the BGA package is mounted onto the first side of the module substrate with a plurality of solder bumps characterized by a melting temperature greater than 200° C.

19. The method of claim 18, wherein the stiffener structure is mounted onto the second side of the module substrate with a solder material characterized by a melting temperature between 150° C.-190° C.

20. The method of claim 17, further comprising bonding a lid to the stiffener structure with a pressure sensitive adhesive.

21. The method of claim 17, further comprising applying a bonding material at least near continuously along a bottom surface of one or more outer walls of the stiffener structure.
